(19) United States
(12) Patent Application Publication
(10) Pub. No.: US 2004/0012308 A1
(43) Pub. Date: Jan. 22, 2004

(54) Piezo-electric bending transducer

(76) Inventor: Michael Riedel, Rodental (DE)

Correspondence Address: HARNESS, DICKEY & PIERCE, P.L.C., P.O.BOX 8910, RESTON, VA, 20195, US

(21) Appl. No.: 10/311,934

(22) PCT Filed: Jun. 18, 2001
(86) PCT No.: PCT/DE01/02250

(30) Foreign Application Priority Data
Jun. 21, 2000 (DE) 10030397.8

(51) Int. Cl. H01L 41/04

(52) U.S. Cl. 310/330

(57) ABSTRACT

The invention relates to a piezo-electric bending transducer (1) with a support (2), comprising a glass, and with a piezo-ceramic coating (4, 5), which is thermally adhered on at least one side to the support (2). According to the invention, a glass is used which has a coefficient of thermal expansion of less than 2×10⁻⁶K. The support (2) preferably comprises a composite consisting of glass fibers (14) and epoxy resin, which can be further reinforced by aramide fibers (15). A bending transformer (1) of this type exhibits a high mechanical deflection capability.

This application is the national phase under 35 U.S.C. § 371 of PCT International Application No. PCT/DE01/02250 which has an International filing date of Jun. 18, 2001, which designated the United States of America and which claims priority on German Patent Application number DE 100 30 397.8 filed Jun. 21, 2000, the entire contents of which are hereby incorporated herein by reference.

### FIELD OF THE INVENTION

The invention generally relates to a piezoelectric bending transducer having a piezoceramic applied onto a support on at least one side.

A piezoelectric bending transducer is primarily used for implementing the indirect or inverse piezoelectric effect, that is to say for converting electrical energy into mechanical energy. There are a large number of technical applications for a bending transducer. Such applications are, for example, as a piezoelectric printing head for an inkjet printer, as a sound pickup or generator for microphones and loudspeakers, respectively, as a sensor for acceleration or pressure measurement, as an actuator in Braille lines in reading devices for the blind, in textile machines, in pneumatic valves, in writing measurement devices or in contactless surface measurement instruments.

### BACKGROUND OF THE INVENTION

According to EP 0 455 342 B1 and EP 0 468 796 A1, a bending transducer is constructed in a layer structure. The piezoceramic is in this case applied onto the support in order to improve the mechanical stability, or for the purpose of better conversion of electrical energy into mechanical energy. For electrical connection, the piezoceramic is provided, optionally on both sides, with electrodes in the form of a flat coat of a conductive material.

Depending on the application, the support may be provided with the described layer sequence on one side or on both sides. According to DE 34 34 726 C2, it is also possible for a plurality of levels of piezoceramics, including the electrodes, to be stacked above another. Depending on the number of piezoceramic layers, the term mono-, bi-, tri-, etc. or generally multi-morph piezoelectric bending transducer is employed.

### SUMMARY OF THE INVENTION

It is an object of an embodiment of the invention to provide a piezoelectric bending transducer which has a good mechanical deflection capability, that is to say a high deflection at a comparatively low operating voltage.

This object may be achieved for the piezoelectric bending transducer, according to an embodiment of the invention, by the fact that the support comprises a glass having a coefficient of thermal expansion of less than 2×10⁻⁶/K, and the coating of the piezoceramic is thermally bonded to the support.

The support may in this case include the glass itself, or of a thermoset which is reinforced by fibers made of the glass.

Extensive studies have shown that when such a glass is used, compared with a normal glass which has a coefficient of thermal expansion of more than 5×10⁻⁶/K, the bending transducer has a higher deflection at the same operating voltage. There is reason to suspect that the better deflection capacity is related to the lower coefficient of thermal expansion.

Since, in a fiber-reinforced thermoset, the coefficient of thermal expansion essentially depends on the fibers that are used, the support has a lower coefficient of thermal expansion when said glass is used than the piezoceramic, whose coefficient of thermal expansion perpendicular to the polarization direction in the short-circuited state generally has a coefficient of thermal expansion of between 4 and 6×10⁻⁶/K. Owing to the heat treatment during the thermal bonding of the coating of the piezoceramic to the support, the piezoceramic therefore remains prestressed to a certain extant after cooling. The distortion of the lattice structure of the piezoceramic due to the prestress has a polarization-supporting effect. The piezoceramic, when thermally bonded to the support comprising the glass, has a higher longitudinal extension or contraction at the same operating voltage than the piezoceramic when not bonded to such a support.

A glass having a coefficient of thermal expansion of less than 2×10⁻⁶/K is, for example, the glass marketed under the brand name “S2 Glass” by Owens Corning Advanced Materials. “S2 Glass” is a registered trademark of Owens Coming. This S2 Glass has a coefficient of thermal expansion of 1.6×10⁻⁶/K. Of course, any other glass, for example a quartz glass, having a coefficient of thermal expansion within the indicated range is suitable to be used for the piezoelectric bending transducer.

Advantageously, the support includes a thermoset reinforced by fibers made of the glass. This offers the advantage of straightforward and cost-effective manufacture. To that end, a so-called prepreg (a soft, pre-impregnated preform containing fibers, which has not yet been cured) is used for the support. The prepreg, together with the piezoceramic intended for the coating, is placed loosely in a suitable mold. Under slight pressure, the prepreg wets the surfaces of the piezoceramic, or of the electrodes applied thereon, and therefore bonds thereto. As a result of a subsequent heat treatment the prepreg is finally cured irreversibly to form the thermoset. Permanent and stable connection of the components of the piezoelectric bending transducer is obtained in a straightforward way.

It is also advantageous for the thermoset to be additionally reinforced with aramid fibers. Besides the increase in the mechanical strength of the support due to the aramid, the mechanical properties of the piezoelectric bending transducer are further improved by the introduction of aramid fibers. This is because aramids have a negative coefficient of thermal expansion of less than −0.5×10⁻⁶/K. In this way, the prestress of the piezoceramic after the manufacturing process is further increased. Suitable aramids are, for example, the aramid marketed under the brand name Kevlar by DuPont, or the aramid available under the brand name Twaron from Akzo Nobel.

In another advantageous configuration of an embodiment of the invention, the fibers are unidirectionally arranged and extend parallel to a predetermined longitudinal direction of the support. In this way, an oriented prestress of the piezoceramic in the longitudinal direction is obtained during the thermal bonding of the prepreg to the piezoceramic coating. The piezoceramic is hence prestressed in the direction of its extension or contraction when an electric field is applied to the electrodes. Owing to the unidirectional alignment, the greatest modulus of elasticity of the support is furthermore obtained in the longitudinal direction. Transverse effects can essentially be neglected.

An epoxy resin is advantageously suitable as the material for the thermoset. A fiber-reinforced epoxy resin configured as a prepreg can be readily and cost-effectively processed to form the piezoelectric bending transducer.

In this case, it is particularly advantageous for the properties of the support if the proportion by mass of the epoxy resin in the support is between 25 and 45 wt. %. A sufficiently great hardness and a sufficiently high flexibility are thereby obtained at the same time.

### BRIEF DESCRIPTION OF THE DRAWINGS

Exemplary embodiments of the invention will be explained in more detail below with the aid of a drawings, in which:

FIG. 1 shows the structure of a piezoelectric bending transducer in a three-dimensional representation, and FIG. 2 shows a section through a piezoelectric bending transducer in an enlarged representation.

Equivalent parts have the same reference numerals.

### DETAILED DESCRIPTION OF THE PREFERRED EMBODIMENTS

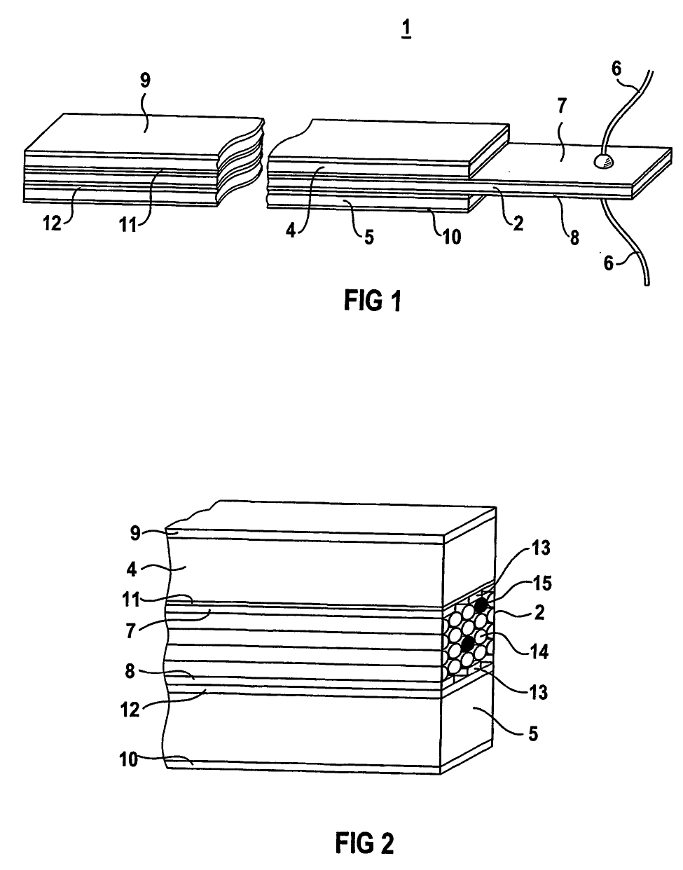

FIG. 1 shows a bi-morph bending transducer 1 having a support 2, and having a first and a second coating 4, 5 of a piezoceramic applied thereon. The piezoceramic is in this case a lead zirconate titanium oxide ceramic. The support 2 is an epoxy resin reinforced with glass fibers. The glass of the fibers is an S2 Glass from Owens Corning Advanced Materials and has a coefficient of thermal expansion of 1.6×10⁻⁶/K. Aramid fibers are also introduced, the weight ratio being between 40:60 and 60:40 in the fiber component. An epoxy resin prepreg was used as the starting material for the support. The prepreg was thermally bonded to the layers 4, 5 of the piezoceramic, and cured, by a heat treatment.

The piezoelectric bending transducer 1 furthermore has electrical terminals 6, which are in each case electrically connected via a soldered contact to electrodes 7 and 8 arranged on the support 2. The layers 4, 5 of the piezoceramic are provided on both sides, in a flat fashion, with electrodes 9, 11 and 10, 12, respectively. At the positions on the support 2 where the layers 4, 5 of the piezoceramic are placed, the electrodes 7 and 8 of the support 2 are (not shown in detail here) not flat, but instead formed as a fabric or in the form of parallel strips. During the heat treatment of the prepreg, the as yet uncured epoxy resin therefore flows through the electrodes 7 and 8 onto the electrodes 11 and 12, and hence, when cured, bonds the support 2 to the layers 4, 5 of the piezoceramic via the electrodes. The electrodes 9, 10, 11 and 12 of the layers 4, 5 of the piezoceramic are in each case designed as a flat coat of a carbon polymer. Owing to the lower coefficient of thermal expansion of the support 2 compared with the coefficient of thermal expansion of the piezoceramic, the latter is prestressed during the thermal bonding.

FIG. 2 shows, in an enlarged representation, a section through the bending transducer 1 shown in FIG. 1. The layers 4, 5 of the piezoceramic can again be seen, together with the electrodes 9, 11 and 10, 12, respectively, applied thereon. The electrodes 7 and 8 applied onto the support 2 are designed as parallel strips 13 extending in the longitudinal direction of the support 2. It can be seen clearly that the glass fibers 14 and the aramid fibers 15 are aligned unidirectionally and in the longitudinal direction of the support 2. In this way, a prestress of the piezoceramic in the longitudinal direction of the support 2 is obtained during the thermal bonding of the prepreg to the layers 4, 5 of the piezoceramic. Owing to the unidirectional alignment of the fibers 14, 15, the greatest modulus of elasticity of the support 2 is furthermore obtained in the longitudinal direction. Transverse effects can be neglected.

The invention being thus described, it will be obvious that the same may be varied in many ways. Such variations are not to be regarded as a departure from the spirit and scope of the invention, and all such modifications as would be obvious to one skilled in the art are intended to be included within the scope of the following claims.

### DESCRIPTION

### Piezoelectric Bending Transducer

The invention relates to a piezoelectric bending transducer having a piezoceramic applied onto a support on at least one side.

A piezoelectric bending transducer of the type mentioned in the introduction is primarily used for implementing the indirect or inverse piezoelectric effect, that is to say for converting electrical energy into mechanical energy. There are a large number of technical applications for a bending transducer. Such applications are, for example, as a piezoelectric printing head for an inkjet printer, as a sound pickup or generator for microphones and loudspeakers, respectively, as a sensor for acceleration or pressure measurement, as an actuator in Braille lines in reading devices for the blind, in textile machines, in pneumatic valves, in writing measurement devices or in contactles,s surface measurement instruments.

According to EP 0 455 342 B1 and EP 0 468 796 A1, a bending transducer is constructed in a layer structure. The piezoceramic is in this case applied onto the support in order to improve the mechanical stability, or for the purpose of better conversion of electrical energy into mechanical energy. For electrical connection, the piezoceramic is provided, optionally on both sides, with electrodes in the form of a flat coat of a conductive material.

Depending on the application, the support may be provided with the described layer sequence on one side or on both sides. According to DE 34 34 726 C2, it is also possible for a plurality of levels of piezoceramics, including the electrodes, to be stacked above another. Depending on the number of piezoceramic layers, the term mono-, bi-, tri-, etc. or generally multi-morph piezoelectric bending transducer is employed.

It is an object of the invention to provide a piezoelectric bending transducer which has a good mechanical deflection capability, that is to say a high deflection at a comparatively low operating voltage.

This object is achieved for the piezoelectric bending transducer, according to the invention, by the fact that the support comprises a glass having a coefficient of thermal expansion of less than 2×10⁻⁶/K, and the coating of the piezoceramic is thermally bonded to the support.

The support may in this case consist of the glass itself, or of a thermoset which is reinforced by fibers made of the glass.

Extensive studies have shown that when such a glass is used, compared with a normal glass which has a coefficient of thermal expansion of more than 5×10⁻⁶/K, the bending transducer has a higher deflection at the same operating voltage. There is reason to suspect that the better deflection capacity is related to the lower coefficient of thermal expansion.

Since, in a fiber-reinforced thermoset, the coefficient of thermal expansion essentially depends on the fibers that are used, the support has a lower coefficient of thermal expansion when said glass is used than the piezoceramic, whose coefficient of thermal expansion perpendicular to the polarization direction in the short-circuited state generally has a coefficient of thermal expansion of between 4 and 6×10⁻⁶/K. Owing to the heat treatment during the thermal bonding of the coating of the piezoceramic to the support, the piezoceramic therefore remains prestressed to a certain extant after cooling. The distortion of the lattice structure of the piezoceramic due to the prestress has a polarization-supporting effect. The piezoceramic, when thermally bonded to the support comprising said glass, has a higher longitudinal extension or contraction at the same operating voltage than the piezoceramic when not bonded to such a support.

A glass having a coefficient of thermal expansion of less than 2×10⁻⁶K is, for example, the glass marketed under the brand name “S2 Glass” by Owens Corning Advanced Materials. “S2 Glass” is a registered trademark of Owens Corning. This S2 Glass has a coefficient of thermal expansion of 1.6×10⁻⁶/K. Of course, any other glass, for example a quartz glass, having a coefficient of thermal expansion within the indicated range is suitable to be used for the piezoelectric bending transducer.

Advantageously, the support comprises a thermoset reinforced by fibers made of the glass. This offers the advantage of straightforward and cost-effective manufacture. To that end, a so-called prepreg (a soft, pre-impregnated preform containing fibers, which has not yet been cured) is used for the support. The prepreg, together with the piezoceramic intended for the coating, is placed loosely in a suitable mold. Under slight pressure, the prepreg wets the surfaces of the piezoceramic, or of the electrodes applied thereon, and therefore bonds thereto. As a result of a subsequent heat treatment the prepreg is finally cured irreversibly to form the thermoset. Permanent and stable connection of the components of the piezoelectric bending transducer is obtained in a straightforward way.

It is also advantageous for the thermoset to be additionally reinforced with aramid fibers. Besides the increase in the mechanical strength of the support due to the aramid, the mechanical properties of the piezoelectric bending transducer are further improved by the introduction of aramid fibers. This is because aramids have a negative coefficient of thermal expansion of less than −0.5×10⁻⁶/K. In this way, the prestress of the piezoceramic after the manufacturing process is further increased. Suitable aramids are, for example, the aramid marketed under the brand name Kevlar by DuPont, or the aramid available under the brand name Twaron from Akzo Nobel.

In another advantageous configuration of the invention, the fibers are unidirectionally arranged and extend parallel to a predetermined longitudinal direction of the support. In this way, an oriented prestress of the piezoceramic in the longitudinal direction is obtained during the thermal bonding of the prepreg to the piezoceramic coating. The piezoceramic is hence prestressed in the direction of its extension or contraction when an electric field is applied to the electrodes. Owing to the unidirectional alignment, the greatest modulus of elasticity of the support is furthermore obtained in the longitudinal direction. Transverse effects can essentially be neglected.

An epoxy resin is advantageously suitable as the material for the thermoset. A fiber-reinforced epoxy resin configured as a prepreg can be readily and cost-effectively processed to form the piezoelectric bending transducer.

In this case, it is particularly advantageous for the properties of the support if the proportion by mass of the epoxy resin in the support is between 25 and 45 wt. %. A sufficiently great hardness and a sufficiently high flexibility are thereby obtained at the same time.

Exemplary embodiments of the invention will be explained in more detail below with the aid of a drawing, in which:

FIG. 1 shows the structure of a piezoelectric bending transducer in a three-dimensional representation, and

FIG. 2 shows a section through a piezoelectric bending transducer in an enlarged representation.

Equivalent parts have the same reference numerals.

FIG. 1 shows a bi-morph bending transducer 1 having a support 2, and having a first and a second coating 4, 5 of a piezoceramic applied thereon. The piezoceramic is in this case a lead zirconate titanium oxide ceramic. The support 2 is an epoxy resin reinforced with glass fibers. The glass of the fibers is an S2 Glass from Owens Corning Advanced Materials and has a coefficient of thermal expansion of 1.6×10⁻⁶/K. Aramid fibers are also introduced, the weight ratio being between 40:60 and 60:40 in the fiber component. An epoxy resin prepreg was used as the starting material for the support. The prepreg was thermally bonded to the layers 4, 5 of the piezoceramic, and cured, by a heat treatment.

The piezoelectric bending transducer 1 furthermore has electrical terminals 6, which are in each case electrically connected via a soldered contact to electrodes 7 and 8 arranged on the support 2. The layers 4, 5 of the piezoceramic are provided on both sides, in a flat fashion, with electrodes 9, 11 and 10, 12, respectively. At the positions on the support 2 where the layers 4, 5 of the piezoceramic are placed, the electrodes 7 and 8 of the support 2 are (not shown in detail here) not flat, but instead formed as a fabric or in the form of parallel strips. During the heat treatment of the prepreg, the as yet uncured epoxy resin therefore flows through the electrodes 7 and 8 onto the electrodes 11 and 12, and hence, when cured, bonds the support 2 to the layers 4, 5 of the piezoceramic via the electrodes. The electrodes 9, 10, 11 and 12 of the layers 4, 5 of the piezoceramic are in each case designed as a flat coat of a carbon polymer. Owing to the lower coefficient of thermal expansion of the support 2 compared with the coefficient of thermal expansion of the piezoceramic, the latter is prestressed during the thermal bonding.

FIG. 2 shows, in an enlarged representation, a section through the bending transducer 1 shown in FIG. 1. The layers 4, 5 of the piezoceramic can again be seen, together with the electrodes 9, 11 and 10, 12, respectively, applied thereon. The electrodes 7 and 8 applied onto the support 2 are designed as parallel strips 13 extending in the longitudinal direction of the support 2. It can be seen clearly that the glass fibers 14 and the aramid fibers 15 are aligned unidirectionally and in the longitudinal direction of the support 2. In this way, a prestress of the piezoceramic in the longitudinal direction of the support 2 is obtained during the thermal bonding of the prepreg to the layers 4, 5 of the piezoceramic. Owing to the unidirectional alignment of the fibers 14, 15, the greatest modulus of elasticity of the support 2 is furthermore obtained in the longitudinal direction. Transverse effects can be neglected.

1. A piezoelectric bending transducer (1) having a support (2), which comprises a glass, and having a coating of a piezoceramic (4, 5) thermally bonded to the support (2) on at least one side, the glass having a coefficient of thermal expansion of less than 2×10⁻⁶/K:

2. The piezoelectric bending transducer (1) as claimed in claim 1, in which the support (2) comprises a thermoset reinforced by fibers (14) made of the glass.

3. The piezoelectric bending transducer (1) as claimed in claim 1 or 2, in which the thermoset is additionally reinforced with aramid fibers (15).

4. The piezoelectric bending transducer (1) as claimed in claim 2 or 3, in which the support (2) extends in a longitudinal direction, and the fibers (14, 15) are arranged unidirectionally and parallel to the longitudinal direction.

5. The piezoelectric bending transducer (1) as claimed in one of claims 2 to 4, in which the thermoset is an epoxy resin.

6. The piezoelectric bending transducer (1) as claimed in claim 8, having a proportion of the epoxy resin in the support (2) of between 25 and 45 wt. %. unidirectionally and parallel to the longitudinal direction.

5. The piezoelectric bending transducer as claimed in claim 2, wherein the thermoset is an epoxy resin.

6. The piezoelectric bending transducer as claimed in claim 5, comprising a proportion of the epoxy resin in the support of between 25 and 45 wt. %.

7. The piezoelectric bending transducer as claimed in claim 3, wherein the support extends in a longitudinal direction, and wherein the fibers are arranged unidirectionally and parallel to the longitudinal direction.

8. The piezoelectric bending transducer as claimed in claim 3, wherein the thermoset is an epoxy resin.

9. The piezoelectric bending transducer as claimed in claim 4, wherein the thermoset is an epoxy resin.

10. The piezoelectric bending transducer as claimed in claim 8, comprising a proportion of the epoxy resin in the support of between 25 and 45 wt. %.

11. The piezoelectric bending transducer as claimed in claim 9, comprising a proportion of the epoxy resin in the support of between 25 and 45 wt. %.

12. The piezoelectric bending transducer as claimed in claim 1, wherein the support includes a composite including glass fibers.

13. The piezoelectric bending transducer as claimed in claim 12, wherein the support additionally includes aramid fibers.
